(19) United States
(12) Patent Application Publication
(10) Pub. No.: US 2025/0180706 A1
(43) Pub. Date: Jun. 5, 2025

(54) Multi-function emitter array

(71) Applicant: Apple Inc., Cupertino, CA (US)

(72) Inventors: Omer Korech, Pardes Hanna Karkur (IL); Nicolas Hotellier, Jarrie (FR); Fei Tan, San Jose, CA (US); Niv Gilboa, Tel Aviv (IL); Scott T. Smith, San Jose, CA (US); Roei Remez, Tel Aviv (IL); Bernhard Buettgen, San Jose, CA (US)

(21) Appl. No.: 18/759,319

(22) Filed: Jun. 28, 2024

Related U.S. Application Data
(60) Provisional application No. 63/604,204, filed on Nov. 30, 2023.

(51) Int. Cl. G01S 7/481; G01S 7/484; H01S 5/02253; H01S 5/183

(52) U.S. Cl. CPC G01S 7/4815; G01S 7/484; H01S 5/02253; H01S 5/18388

(57) ABSTRACT

An optoelectronic device includes a semiconductor substrate and an array of emitters disposed on the substrate. The array includes a first sub-array, having a first pitch, disposed in a peripheral area of the substrate, a second sub-array, also having the first pitch, disposed in a central area of the substrate, which is contained within the peripheral area, and a third sub-array, having a second pitch finer than the first pitch, interleaved with the second sub-array in the central area of the substrate. Conductors disposed on the substrate are configured to activate the first, second, and third sub-arrays selectively.

### CROSS-REFERENCE TO RELATED APPLICATION

This application claims the benefit of U.S. Provisional Patent Application 63/604,204, filed Nov. 30, 2023, which is incorporated herein by reference.

### FIELD OF THE INVENTION

The present invention relates generally to optoelectronic devices, and particularly to optical emitter arrays.

### BACKGROUND

Optical depth mapping systems are used for generating a three-dimensional (3D) profile of the surface of an object by processing optical radiation reflected from the object. This sort of 3D profile is also referred to as a 3D map, depth map or depth image, and depth mapping is also referred to as 3D mapping. (In the context of the present description and in the claims, the terms “optical radiation” and “light” are used interchangeably to refer to electromagnetic radiation in any of the visible, infrared and ultraviolet ranges of the spectrum.)

Some depth mapping systems operate by measuring the time of flight (ToF) of radiation to and from points in the object. In direct TOF (dToF) systems, a light transmitter, such as a laser or array of lasers, directs short pulses of light toward the object. A receiver, such as a sensitive, high-speed photodiode (for example, an avalanche photodiode) or an array of such photodiodes, receives the light returned from the scene. Control circuitry measures the time delay between the transmitted and received light pulses at each point in the object, which is indicative of the distance traveled by the light beam, and hence of the depth of the object at the point, and uses the depth data thus extracted in producing a 3D map of the object.

In some applications, radiation sources of different focal qualities are combined into a single optoelectronic apparatus comprising an optical element, such as a lens, and two monolithic emitter arrays, both of which emit optical beams through the optical element. For example, U.S. Pat. No. 11,710,945, whose disclosure is incorporated herein by reference, describes such an apparatus in which one of the arrays is positioned at the rear focal plane of the optical element, while the other array is displaced from the rear focal plane. The beams emitted by the array at the rear focal plane are projected by the element as collimated beams, thus projecting patterned radiation on a target region in a pattern corresponding to the layout of the emitters in the array. The beams emitted by the array that is displaced from the rear focal plane are defocused.

### SUMMARY

Embodiments of the present invention that are described hereinbelow provide improved illumination devices and methods for their design and operation.

There is therefore provided, in accordance with an embodiment of the invention, an optoelectronic device, including a semiconductor substrate and an array of emitters disposed on the substrate. The array includes a first sub-array, having a first pitch, disposed in a peripheral area of the substrate, a second sub-array, also having the first pitch, disposed in a central area of the substrate, which is contained within the peripheral area, and a third sub-array, having a second pitch finer than the first pitch, interleaved with the second sub-array in the central area of the substrate. Conductors disposed on the substrate are configured to activate the first, second, and third sub-arrays selectively.

In some embodiments, the device includes microlenses disposed respectively over the emitters in one or more of the sub-arrays. In a disclosed embodiment, the microlenses include on-chip lenses formed respectively on the emitters.

Additionally or alternatively the microlenses include first microlenses, having a first radius of curvature and disposed respectively over the emitters in the first sub-array, and second microlenses, having a second radius of curvature, greater than the first radius of curvature, and disposed respectively over the emitters in the second sub-array. In a disclosed embodiment, the first and second radii of curvature are selected to reduce a divergence of beams emitted by the emitters in the first and second sub-arrays.

In some embodiments, the microlenses are disposed only over the emitters in the first and second sub-arrays and not over the emitters in the third sub-array. In a disclosed embodiment, the device includes projection optics mounted over the semiconductor substrate and configured to project first and second beams emitted by the emitters in the first and second sub-arrays to produce a pattern of spots over a first field of view and to project the second beams and third beam emitted by the emitters in the third sub-array to project flood illumination over a second field of view, which is contained within the first field of view.

In some embodiments, the device includes a controller coupled to the conductors and configured to activate the first and second sub-arrays simultaneously to project a pattern of spots over a first field of view and to activate the second and third sub-arrays simultaneously to project flood illumination over a second field of view, which is contained within the first field of view. In one embodiment, the controller is configured to activate all the emitters in the second and third sub-arrays to project the flood illumination over the second field of view and to activate a subset of the emitters in the second and third sub-arrays to project the flood illumination over a third field of view, which is contained within the second field of view.

In a disclosed embodiment, the emitters include vertical-cavity surface-emitting lasers (VCSELs). Additionally or alternatively, the second pitch is half the first pitch.

In some embodiments, the first and second sub-arrays define a rectangular array. Alternatively, the first and second sub-arrays define a hexagonal array.

There is also provided, in accordance with an embodiment of the invention, a method for optical projection, which includes providing an array of emitters disposed on a substrate. The array includes a first sub-array, having a first pitch, disposed in a peripheral area of the substrate, a second sub-array, also having the first pitch, disposed in a central area of the substrate, which is contained within the peripheral area, and a third sub-array, having a second pitch finer than the first pitch, interleaved with the second sub-array in the central area of the substrate. The first, second, and third sub-arrays are activated selectively to project patterns of radiation.

The present invention will be more fully understood from the following detailed description of the embodiments thereof, taken together with the drawings in which:

### BRIEF DESCRIPTION OF THE DRAWINGS

FIG. 1 is a schematic frontal view of an optoelectronic device, in accordance with an embodiment of the invention;

FIG. 2 is a schematic side view of an optical projector incorporating the device of FIG. 1, in accordance with an embodiment of the invention; and

FIG. 3 is a schematic frontal view of an optoelectronic device, in accordance with another embodiment of the invention.

### DETAILED DESCRIPTION OF EMBODIMENTS

### Overview

Many optical imaging systems have multiple modes of operation, with different angular properties. For example, a dTOF-based depth mapping system may have both a “wide mode,” with a wide field of view, a wide field of illumination (FOI) on the target scene, and coarse angular resolution, and a “narrow mode,” with a narrow FOI and fine angular resolution over a narrow field of view. The wide mode may be implemented by illuminating a target scene with a discrete set of illumination spots and imaging these spots onto a detector array. In the narrow mode, the target scene is illuminated with spatially continuous illumination (flood illumination) to take advantage of the fine angular resolution of the detector array.

For these sorts of applications, there is a need for a simple, compact, and low-cost illuminator architecture capable of providing both wide-mode spot illumination and narrow-mode flood illumination. Embodiments of the present invention that are described herein address this need with an illuminator architecture based on a single, monolithic emitter array. This architecture is suited not only for dToF-based depth mapping, but also for other depth mapping and imaging applications that support multiple resolution levels and multiple fields of illumination.

In the disclosed embodiments, the emitter array is formed on a semiconductor substrate and has a central area and a peripheral area, which surrounds the central area. The array comprises three emitter sub-arrays, with conductors that enable a controller to activate the sub-arrays selectively. First and second sub-arrays, with a common first pitch, are activated together to generate wide-mode spot illumination. The first sub-array is disposed in the peripheral area of the substrate, while the second sub-array is disposed in the central area. A third sub-array is interleaved in the central area of the substrate with the emitters of the second sub-array and has a second pitch that is finer than the first pitch. The second and third sub-arrays thus form a dense emitter array covering the central area and are activated together to generate narrow-mode flood illumination.

The term “pitch,” as used in the present description and in the claims in regard to the sub-arrays, refers to the minimal distance between adjacent emitters in a given sub-array. In some cases, a minority of the emitters in a sub-array may be separated from one or more of their neighbors in the sub-array by a distance greater than the pitch, for example due to interleaving of the second sub-array in the third sub-array, as illustrated in the figures that follow.

In some embodiments, microlenses, such as on-chip lenses formed on the semiconductor substrate, are disposed over at least some of the emitters. For example, in one embodiment, microlenses are formed over the emitters in the first and second sub-arrays to reduce the divergence of the beams generated by these emitters. Projection optics, mounted over the emitter array, collimate the beams of optical radiation that are emitted when the controller activates the first and second sub-arrays to project a wide array of discrete spots onto the target scene. When the controller activates the second and third sub-arrays, the projection optics project the beams to illuminate a narrower area with continuous flood illumination.

Thus, the present embodiments provide a multi-mode illuminator that is simple, compact, and low in cost, requiring only a single emitter array and projection optics, without moving parts.

### Optoelectronic Devices

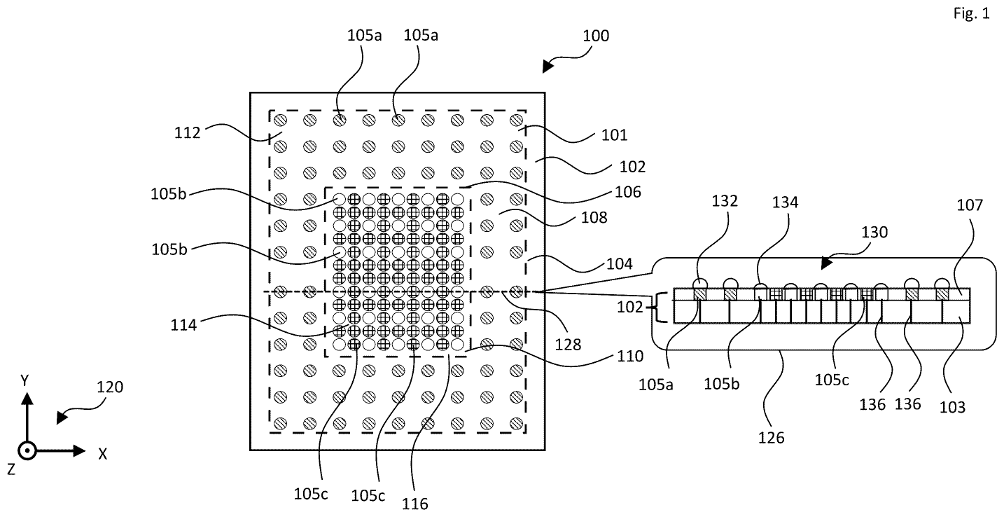

FIG. 1 is a schematic frontal view of an optoelectronic device 100, in accordance with an embodiment of the invention.

Device 100 comprises an emitter array 101, which is formed on a semiconductor substrate 102 using methods of fabrication and semiconductor materials that are known in the art. In the present embodiment, substrate 102 comprises a silicon (Si) die 103, and all emitters in emitter array 101 comprise vertical-cavity surface-emitting lasers (VCSELs) 105, fabricated on a gallium-arsenide (GaAs) layer 107. Emitter array 101 is divided into two areas: A peripheral area 108 defined as the area that is between an outer frame 104 and an inner frame 106, and a central area 110 within the inner frame.

Emitter array 101 comprises three types of VCSELS 105a, 105b, and 105c. These three types of VCSELs can be identical in their structure. For example, all the VCSELs 105 may have the same optical aperture, typically in the range of 5-10 μm (although larger or smaller apertures may alternatively be used). VCSELs 105a, 105b, and 105c differ from one another in their locations, functions, their on-chip microlenses (OCLs) or lack thereof, and in how they are activated, as further detailed hereinbelow. In an alternative embodiment, the three types of VCSELs may have different optical apertures and/or may differ in other structural or optical features.

VCSELs 105 of emitter array 101 are arranged in three rectangular sub-arrays:
A first sub-array 112 in peripheral area 108 comprises VCSELs 105a (shown in FIG. 1 as diagonally cross-hatched circles) having a relatively large pitch, for example on the order of 50 μm.
A second sub-array 114 comprises VCSELs 105b (shown as solid white circles) in central area 110. VCSELs 105b have the same pitch as VCSELs 105a and are aligned with the rows and columns of sub-array 112 in the X- and Y-directions (with reference to Cartesian coordinates 120). Thus, sub-arrays 112 and 114 together form a continuous array with a large pitch over peripheral and central areas 108 and 110, respectively.
A third sub-array 116 comprises VCSELs 105c (shown as circles with a crisscross hatching), which are interleaved with VCSELs 105b in central area 110. The pitch of sub-array 116 is smaller than that of sub-arrays 112 and 114, for example, half the pitch of the other sub-arrays (on the order of 25 μm in this case). The interleaved sub-arrays 114 and 116 together form a compact array of emitters in central area 110.

An inset 126 shows a schematic sectional view 130 of emitter array 101 along a line 128, showing VCSELs 105a, 105b, and 105c with the same hatching scheme as in the frontal view. VCSELs 105 are activated and driven by electrical signals conveyed through respective conductors 136.

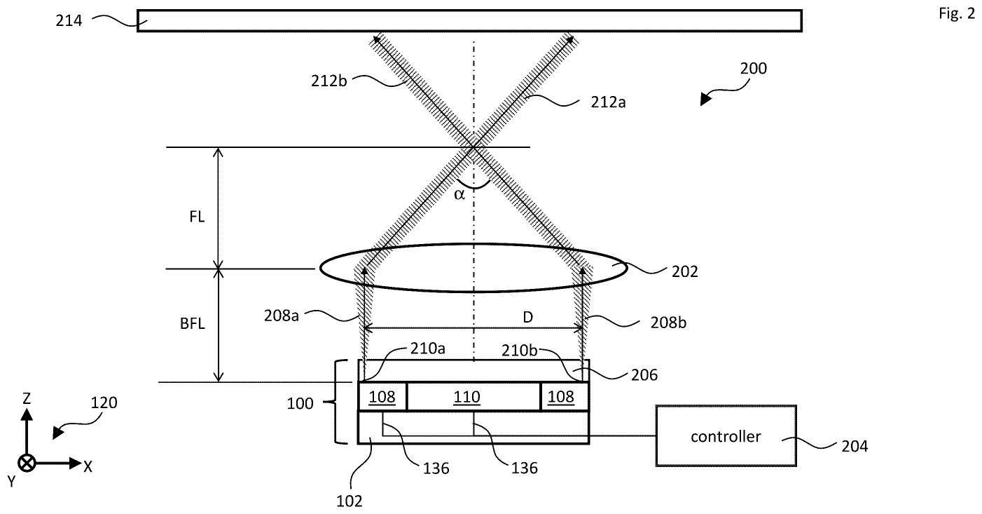

An on-chip microlens (OCL) 132 is formed over each VCSEL 105a, and an OCL 134 is formed over each VCSEL 105b. In this example, OCLs 134 have a longer radius of curvature than the radius of curvature of OCLs 132 (and hence a longer focal length than that of OCLs 132.) OCLs 132 and 134 are designed to reduce the divergence of the beams of optical radiation emitted by VCSELs 105a and 105b so that the beams are projected onto a target scene as collimated beams, as will be further detailed in reference to FIG. 2. As VCSELs 105b have to provide both spot illumination (wide mode) and flood illumination (narrow mode), the longer focal length of lenses 134 is a trade-off between the requirements of spot and flood illumination. In the present embodiment, no OCLs are disposed over VCSELs 105c. Alternatively, OCLs of a different radius of curvature may be formed over VCSELs 105c, possibly including OCLs with negative optical power.

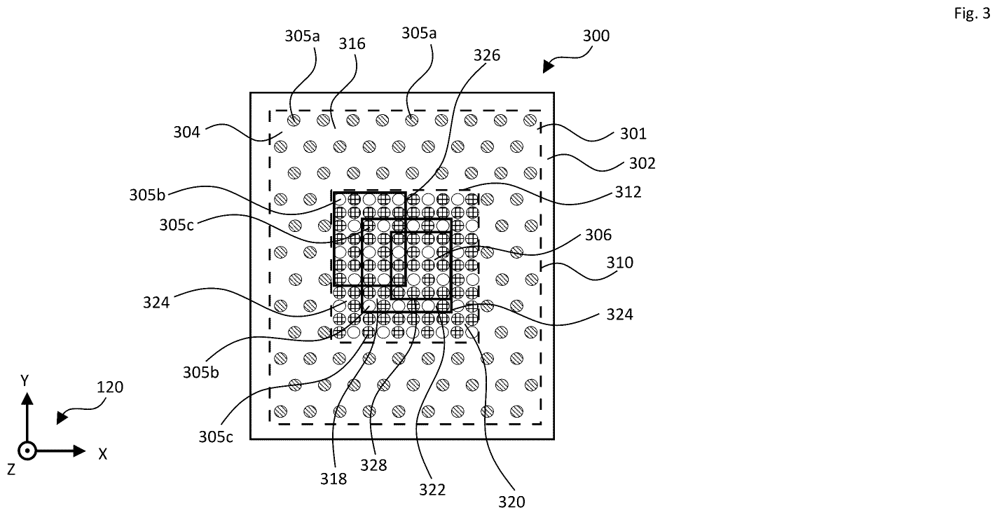

In FIG. 1, sub-arrays 112 and 114 define a rectangular array, meaning that the beams emitted by VCSELs 105a and 105b will form an approximately rectangular array of spots on a target scene (possibly deviating from a precise rectangular form due to optical distortion). In alternative embodiments, VCSELs 105 may be arranged in other forms of arrays, such as a hexagonal array (as shown in FIG. 3).

FIG. 2 is a schematic side view of an optical projector 200 incorporating device 100 (FIG. 1), in accordance with an embodiment of the invention.

Projector 200 comprises device 100, projection optics 202, and a controller 204, and may be used as a light source for a dTOF depth mapping system. Peripheral area 108 and central area of 110 array emitter 101 are shown schematically, without showing the respective VCSELs, and on-chip lenses 132 and 134 are shown schematically as a single lens layer 206. Controller 204 is coupled to conductors 136 (also shown schematically). Depending on the requirements for addressability of the emitters in array 101, controller 204 may be coupled separately to all conductors 136 of all the VCSELs in device 100 or collectively to groups of the conductors, such as the groups of conductors that activate and drive each of sub-arrays 112, 114 and 116.

Controller 204 typically comprises hard-wired and/or programmable hardware logic circuits, which selectively activate VCSELs 105 according to the desired mode of operation. Thus, as noted above, controller 204 may activate VCSELs 105a and 105b to generate wide-angle spot illumination and may activate VCSELs 105b and 105c to generate narrow-angle flood illumination. Additionally or alternatively, controller 204 may comprise a programmable processor, which is programmed in software and/or firmware to carry out at least some of the functions that are described herein. Although controller 204 is shown in FIG. 2, for the sake of simplicity, as a single, monolithic functional block, in practice the controller may comprise a single chip or a set of two or more chips, with suitable interfaces for outputting the signals that are illustrated in the figures and are described in the text. In one embodiment, the controller chip may be stacked beneath substrate 102 using bonding techniques that are known in the art.

FIG. 2 shows beams 208a and 208b emitted by two respective VCSELs 105a and partially focused by respective OCLs 132 at opposing outer edges of peripheral area 108, when controller 204 activates these emitters. Beams 208a and 208b have respective beam waists 210a and 210b. Projection optics 202 are mounted above semiconductor substrate 102 at a distance BFL above beam waists 210a and 210b, wherein BFL is the back focal length of the projection optics. (For example, in a compact projection system, BFL may be between 300 μm and 800 μm, although in alternative embodiments other values may be used.) Consequently, projection optics 202 project beams 208a and 208b as collimated beams 212a and 212b, respectively, toward a target scene 214. Beams 212a and 212b diverge from each other at an angle α, wherein α is determined by the separation D between beams 208a and 208b and the focal length (FL) of projection optics 202. Angle α, in turn, determines the extent of the field of spot illumination on object 214.

When controller 204 activates sub-arrays 112 and 114 (VCSELs 105a in peripheral area 108 and VCSELs 105b in central area 110), beams emitted by the VCSELs illuminate target scene 214 with a spot pattern. Due to the difference between the radii of curvature of OCLs 132 and OCLs 134, as indicated in FIG. 1, the spots illuminated by beams from VCSELs 105b may differ in size from those illuminated by beams from 105a. VCSELS Alternatively, the spots illuminated by beams from VCSELs 105b may have similar sizes but different shapes from those illuminated by beams from VCSELs 105a, due to the inherent increase in beam divergence of tilted off-axis beams relative to paraxial rays (regardless of the OCLs).

When controller 204 activates sub-arrays 114 and 116 (VCSELs 105b and VCSELs 105c, all in central area 110), the beams emitted by these emitters and projected onto target scene 214 by projection optics 202 overlap or touch each other, illuminating the object with a nearly uniform flood illumination. Due to the smaller extent of central area 110, as compared to peripheral area 108, the angular extent of the flood illumination on target scene 214 is less than the extent of the spot pattern described hereinabove.

FIG. 3 is a schematic frontal view of an optoelectronic device 300, in accordance with another embodiment of the invention. Device 300 may be used in projector 200 (FIG. 2) in place of device 100.

Optoelectronic device 300 comprises an emitter array 301, which is disposed on a semiconductor substrate 302, similar to substrate 102 (FIG. 1.) As in the preceding embodiment, all emitters in emitter array 301 comprise identical VCSELs 305. Emitter array 301 is divided into a peripheral area 304 and a central area 306. The division into the two areas is illustrated in the figure with frames 310 and 312, shown as dashed lines. Peripheral area 304 is located between frames 310 and 312, and central area 306 is located within frame 312.

Emitter array 301 comprises, similarly to emitter array 101, three types of VCSELs 305a, 305b, and 305c. Similarly to VCSELs 105 in device 100 (FIG. 1), the three types of VCSELs 305 may be identical in their structure. They differ from each other in their locations, functions, their on-chip microlenses (OCLs) or lack thereof, and in how they are activated, as further detailed hereinbelow.

VCSELs 305 of emitter array 301 are arranged in three sub-arrays:
A first sub-array 316 in peripheral area 304 comprises VCSELs 305a (shown in FIG. 3 as diagonally cross-hatched circles) with a relatively large pitch.
A second sub-array 318 comprises VCSELs 305b (shown as solid white circles) disposed in central area 306, with the same pitch as sub-array 316.
A third sub-array 320 comprises VCSELs 305c (shown as circles with a crisscross hatching), which are interleaved with VCSELs 305b in central area 306 and have pitch that is finer than that of sub-arrays 316 and 318.

VCSELs 305a and 305b may have OCLs similar to those described above. Alternatively, VCSELs 305 may have a different arrangement of microlenses.

Emitters 305a and 305b sub-arrays 316 and 318 define a continuous hexagonal array within frame 310. In this hexagonal array, emitters 305a and 305b are staggered by half the Cartesian pitch from row to row and column to column. When sub-arrays 316 and 318 are activated to project a pattern of spots for a mapping or image system, this staggering can improve the detection of small objects for some common object geometries.

Conductors 136 (shown in FIGS. 1 and 2) are coupled to emitters 305 so as to enable controller 204 to select different subsets of emitters 305b and 305c to be activated for generating different areas of flood illumination. The ability to select different areas can be beneficial, for example, when the collection optics of a mapping or imaging system have two or more different zoom-settings (focal lengths), to enable the field of illumination to match the varying field of view of the collection optics. Thus, for example, only a subset 322 of VCSELs 305b and 305c, defined by a frame 324, shown as a solid line, may be activated to provide flood illumination for a long zoom setting, while all of VCSELs 305b and 305c in central area 306 (within frame 312) are used to provide flood illumination for a shorter zoom setting. For the long zoom setting, VCSELs 305b and 305c in subset 322 may be driven with higher power than is applied at the shorter zoom setting.

Further subsets of emitters 305b and 305c in respective second sub-array 318 and third sub-array 320 may be activated to provide flood illumination to selected regions of interest (ROI) within the FOI. An ROI of this sort may be useful for mapping or imaging a sub-area containing details of interest and can provide a faster cycle time and lower energy consumption for repeated mapping or imaging of the ROI. Thus, VCSELs 305b and 305c may be activated only within a frame 326, shown as a solid black line, defining an ROI for flood illumination within frame 312. Alternatively, VCSELs 305b and 305c within a frame 328, shown as a solid line, may be activated to illuminate an ROI within frame 324. Frames 326 and 328 are shown only as examples of selecting ROIs. Other ROIs may be selected by suitable addressing of a subset of VCSELS 305.

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An optoelectronic device, comprising:
a semiconductor substrate;
an array of emitters disposed on the substrate, the array comprising:
a first sub-array, having a first pitch, disposed in a peripheral area of the substrate;
a second sub-array, also having the first pitch, disposed in a central area of the substrate, which is contained within the peripheral area; and
a third sub-array, having a second pitch finer than the first pitch, interleaved with the second sub-array in the central area of the substrate; and
conductors disposed on the substrate and configured to activate the first, second, and third sub-arrays selectively.

2. The device according to claim 1, and comprising microlenses disposed respectively over the emitters in one or more of the sub-arrays.

3. The device according to claim 2, wherein the microlenses comprise on-chip lenses formed respectively on the emitters.

4. The device according to claim 2, wherein the microlenses comprise:
first microlenses, having a first radius of curvature and disposed respectively over the emitters in the first sub-array; and
second microlenses, having a second radius of curvature, greater than the first radius of curvature, and disposed respectively over the emitters in the second sub-array.

5. The device according to claim 4, wherein the first and second radii of curvature are selected to reduce a divergence of beams emitted by the emitters in the first and second sub-arrays.

6. The device according to claim 2, wherein the microlenses are disposed only over the emitters in the first and second sub-arrays and not over the emitters in the third sub-array.

7. The device according to claim 6, and comprising projection optics mounted over the semiconductor substrate and configured to project first and second beams emitted by the emitters in the first and second sub-arrays to produce a pattern of spots over a first field of view and to project the second beams and third beam emitted by the emitters in the third sub-array to project flood illumination over a second field of view, which is contained within the first field of view.

8. The device according to claim 1, and comprising a controller coupled to the conductors and configured to activate the first and second sub-arrays simultaneously to project a pattern of spots over a first field of view and to activate the second and third sub-arrays simultaneously to project flood illumination over a second field of view, which is contained within the first field of view.

9. The device according to claim 8, wherein the controller is configured to activate all the emitters in the second and third sub-arrays to project the flood illumination over the second field of view and to activate a subset of the emitters in the second and third sub-arrays to project the flood illumination over a third field of view, which is contained within the second field of view.

10. The device according to claim 1, wherein the emitters comprise vertical-cavity surface-emitting lasers (VCSELs).

11. The device according to claim 1, wherein the second pitch is half the first pitch.

12. The device according to claim 1, wherein the first and second sub-arrays define a rectangular array.

13. The device according to claim 1, wherein the first and second sub-arrays define a hexagonal array.

14. A method for optical projection, comprising:
providing an array of emitters disposed on a substrate, the array comprising:
a first sub-array, having a first pitch, disposed in a peripheral area of the substrate;
a second sub-array, also having the first pitch, disposed in a central area of the substrate, which is contained within the peripheral area; and
a third sub-array, having a second pitch finer than the first pitch, interleaved with the second sub-array in the central area of the substrate; and
activating the first, second, and third sub-arrays selectively to project patterns of radiation.

15. The method according to claim 14, wherein providing the array comprises positioning microlenses respectively over the emitters in one or more of the sub-arrays.

16. The method according to claim 15, wherein the microlenses comprise:
first microlenses, having a first radius of curvature and disposed respectively over the emitters in the first sub-array; and
second microlenses, having a second radius of curvature, greater than the first radius of curvature, and disposed respectively over the emitters in the second sub-array.

17. The method according to claim 15, wherein the microlenses are disposed only over the emitters in the first and second sub-arrays and not over the emitters in the third sub-array.

18. The method according to claim 14, wherein activating the first, second, third and sub-arrays comprises activating the first and second sub-arrays simultaneously to project a pattern of spots over a first field of view and activating the second and third sub-arrays simultaneously to project flood illumination over a second field of view, which is contained within the first field of view.

19. The method according to claim 18, wherein activating the second and third sub-arrays comprises activating all the emitters in the second and third sub-arrays to project the flood illumination over the second field of view and to activating a subset of the emitters in the second and third sub-arrays to project the flood illumination over a third field of view, which is contained within the second field of view.

20. The method according to claim 14, wherein the second pitch is half the first pitch.
